(19) United States
(12) Patent Application Publication
(10) Pub. No.: US 2025/0023326 A1
(43) Pub. Date: Jan. 16, 2025

(54) SEMICONDUCTOR LASER DEVICE

(71) Applicant: ROHM CO., LTD., Kyoto (JP)

(72) Inventors: Keiji HIDAKA, Kyoto-shi (JP); Yoshinori TANAKA, Kyoto-shi (JP); Junxiong NIU, Kyoto-shi (JP)

(73) Assignee: ROHM CO., LTD., Kyoto (JP)

(21) Appl. No.: 18/896,644

(22) Filed: Sep. 25, 2024

Related U.S. Application Data
(63) Continuation of application No. PCT/JP2023/005688, filed on Feb. 17, 2023.

(30) Foreign Application Priority Data
Mar. 30, 2022 (JP) 2022-056082

(51) Int. Cl. H01S 5/042; H01S 5/02; H01S 5/34

(52) U.S. Cl. CPC H01S 5/0421; H01S 5/0206; H01S 5/3416

(57) ABSTRACT

A semiconductor laser device includes a semiconductor substrate, a light emitting unit, a contact layer, an insulating film, and a first electrode. The contact layer has an electrode connection surface facing the Z direction. The insulating film has a pair of contact layer covering parts that cover both end regions of the electrode connection surface in the X direction, and a first opening that exposes a portion of the electrode connection surface. The first electrode is connected to the electrode connection surface exposed from the first opening. The insulation coverage factor, which is the ratio of the width of the pair of contact layer covering parts in the X direction to the width of the electrode connection surface in the X direction, is 10% or less. The thickness of the contact layer in the Z direction is 2 μm or greater.

### CROSS-REFERENCE TO RELATED APPLICATIONS

This application is a continuation of, and claims the benefit of priority from International Application No. PCT/JP2023/005688, filed on Feb. 17, 2023, which claims the benefit of priority from Japanese Patent Application No. 2022-056082, filed on Mar. 30, 2022, the entire contents of each of which are incorporated herein by reference.

### BACKGROUND

### 1. Field

The following description relates to a semiconductor laser device.

### 2. Description of Related Art

Japanese Laid-Open Patent Publication No. 2019-186387 discloses a semiconductor laser device. The semiconductor laser device includes a light emitter that has a double heterostructure including an n-type cladding layer, an active layer, and a p-type cladding layer. The semiconductor laser device emits laser light from an end surface of the light emitter.

### BRIEF DESCRIPTION OF THE DRAWINGS

FIG. 1 is a perspective view showing one embodiment of a semiconductor laser device.

FIG. 2 is a cross-sectional view of the semiconductor laser device shown in FIG. 1.

FIG. 3 is a diagram showing an exemplary structure of a light emitting unit shown in FIG. 2.

FIG. 4 is a diagram showing an exemplary structure of an active layer shown in FIG. 3.

FIG. 5 is a diagram showing an exemplary structure of a tunnel layer shown in FIG. 2.

FIG. 6 is a diagram showing a state of laser light emitted from the semiconductor laser device shown in FIG. 1.

FIG. 7 is a diagram showing the relationship of insulation coverage, thickness of a contact layer, and a state of laser light in experimental examples of a semiconductor laser device.

FIG. 8A is a diagram showing a far field pattern of a semiconductor laser device in an experimental example.

FIG. 8B is a diagram showing a near field pattern of the semiconductor laser device in the experimental example.

FIG. 9A is a diagram showing a far field pattern of a semiconductor laser device in an experimental example.

FIG. 9B is a diagram showing a near field pattern of the semiconductor laser device in the experimental example.

FIG. 10A is a diagram showing a far field pattern of a semiconductor laser device in an experimental example.

FIG. 10B is a diagram showing a near field pattern of the semiconductor laser device in the experimental example.

FIG. 11A is a diagram showing a far field pattern of a semiconductor laser device in an experimental example.

FIG. 11B is a diagram showing a near field pattern of the semiconductor laser device in the experimental example.

FIG. 12 is a cross-sectional view showing a modified example of a semiconductor laser device.

FIG. 13 is a cross-sectional view showing a modified example of a semiconductor laser device.

### DETAILED DESCRIPTION

Embodiments of a semiconductor laser device according to the present disclosure will be described below with reference to the drawings. In the drawings, components may not be drawn to scale for simplicity and clarity of illustration. In a cross-sectional view, hatching may be omitted to facilitate understanding. The accompanying drawings only illustrate embodiments of the present disclosure and are not intended to limit the present disclosure. In addition, in this specification, “parallel,” “perpendicular,” “orthogonal,” and “constant” in this specification are not limited to exactly parallel, exactly perpendicular, exactly orthogonal, and exactly constant and include generally parallel, generally perpendicular, generally orthogonal, and generally constant within the scope in which the operation and advantages of the embodiment are obtained. In this specification, “equal” includes exact equal and a case in which compared subjects slightly differ from each other due to dimensional tolerances or the like.

In this specification, “at least one of A and B” should be understood to mean “only A, only B, or both A and B.”

The following detailed description includes exemplary embodiments of a device, a system, and a method according to the present disclosure. The detailed description is illustrative and is not intended to limit embodiments of the present disclosure or the application and use of the embodiments.

### Embodiments

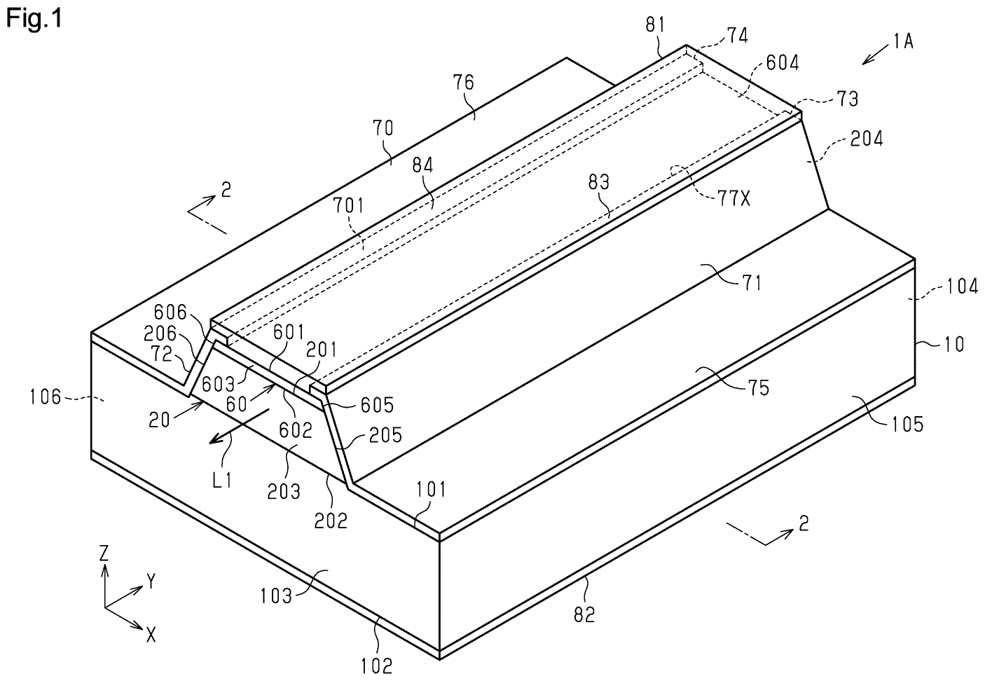

One embodiment of a semiconductor laser device 1A will be described with reference to FIGS. 1 to 6.

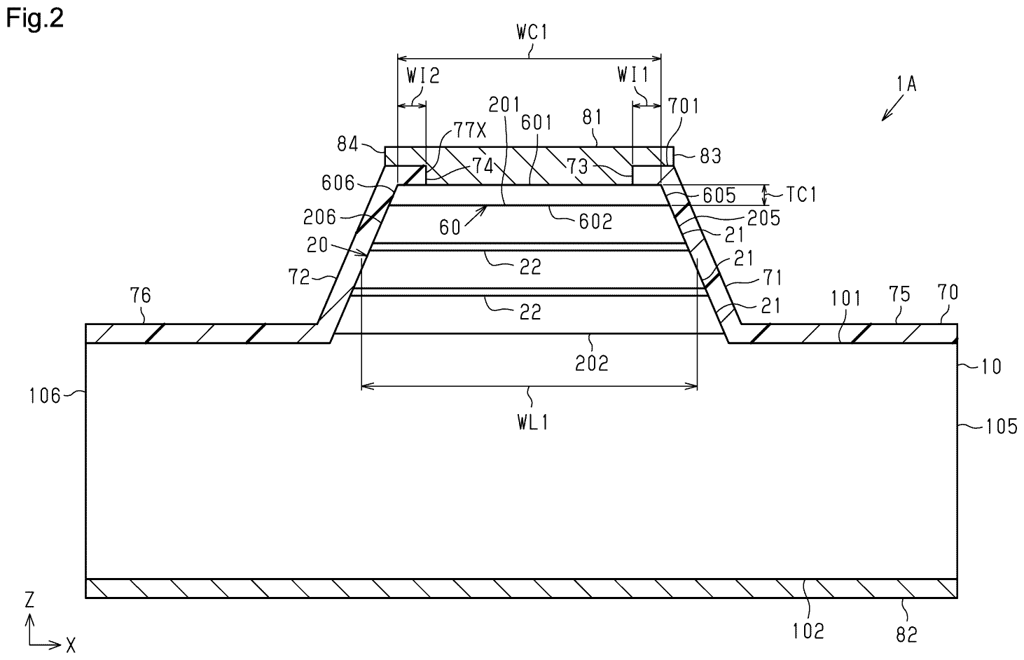

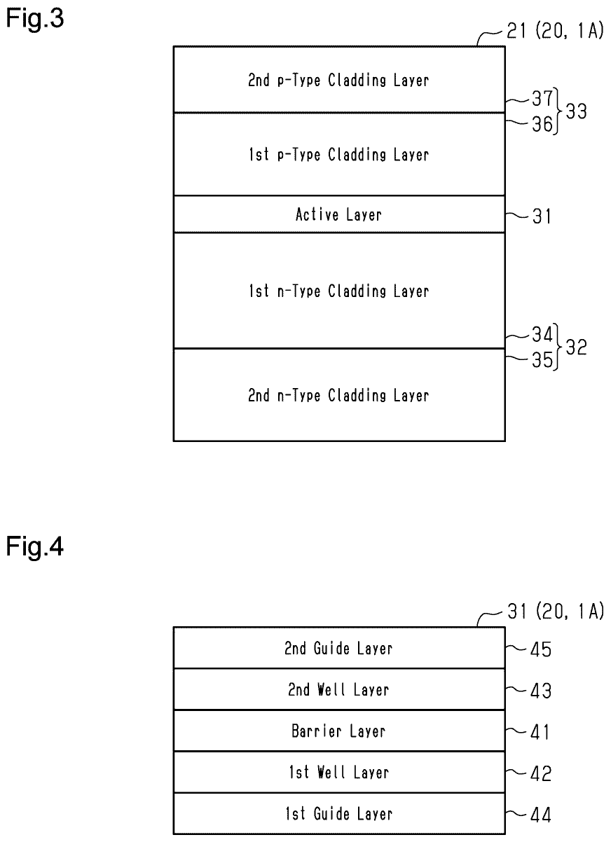

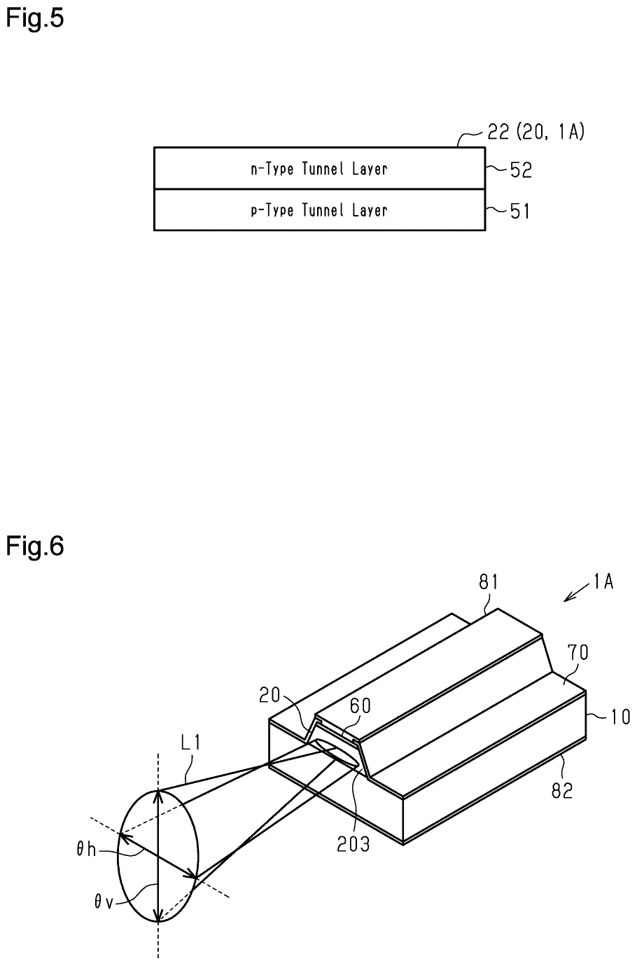

FIG. 1 is a perspective view showing one embodiment of a semiconductor laser device. FIG. 2 is a cross-sectional view of the semiconductor laser device shown in FIG. 1. FIG. 3 is a diagram showing an exemplary structure of a light emitting unit shown in FIG. 2. FIG. 4 is a diagram showing an exemplary structure of an active layer shown in FIG. 3. FIG. 5 is a diagram showing an exemplary structure of a tunnel layer shown in FIG. 2. FIG. 6 is a diagram showing an emission pattern of laser light emitted from the semiconductor laser device shown in FIG. 1.

### Overall Structure of Semiconductor Laser Device

As shown in FIGS. 1 and 2, the semiconductor laser device 1A includes a semiconductor substrate 10, a light emitter 20, a contact layer 60, an insulation film 70, a first electrode 81, and a second electrode 82.

### Semiconductor Substrate

The semiconductor substrate 10 includes a substrate main surface 101, a substrate back surface 102, and substrate side surfaces 103, 104, 105, and 106. The substrate main surface 101 and the substrate back surface 102 face opposite directions. A direction perpendicular to the substrate main surface 101 is referred to as a Z-direction (thickness-wise direction, first direction). A direction orthogonal to the Z-direction is referred to as a Y-direction (second direction). A direction orthogonal to the Z-direction and the Y-direction is referred to as an X-direction (third direction). The substrate side surfaces 103 and 104 face opposite directions in the Y-direction. The substrate side surfaces 105 and 106 face opposite directions in the X-direction. As viewed in the Z-direction, the semiconductor substrate 10 is rectangular and elongated in the Y-direction.

The semiconductor substrate 10 is, for example, rectangular-plate-shaped. The semiconductor substrate 10 includes, for example, an n-type semiconductor substrate (n-GaAs substrate) including gallium-arsenic (GaAs). The semiconductor substrate 10 includes, for example, at least one of silicon (Si), tellurium (Te), and selenium (Se) as an n-type impurity.

### Light Emitter

The light emitter 20 is arranged on the substrate main surface 101 of the semiconductor substrate 10. The light emitter 20 projects from the substrate main surface 101 in a direction opposite from the substrate back surface 102. In other words, the light emitter 20 projects from the substrate main surface 101 in the Z-direction.

The light emitter 20 includes a contact layer connection surface 201, a substrate connection surface 202, light emitter end surfaces 203 and 204, and light emitter side surfaces 205 and 206. The contact layer connection surface 201 and the substrate main surface 101 face the same direction in the Z-direction. The substrate connection surface 202 faces the semiconductor substrate 10. The substrate connection surface 202 is connected to the substrate main surface 101. The light emitter end surfaces 203 and 204 are two end surfaces of the light emitter 20 in the Y-direction. The light emitter end surfaces 203 and 204 face opposite directions in the Y-direction. The light emitter side surfaces 205 and 206 are two ends surfaces of the light emitter 20 in the X-direction. The light emitter side surfaces 205 and 206 face opposite directions in the X-direction. The light emitter side surfaces 205 and 206 connect the contact layer connection surface 201 and the substrate connection surface 202. The light emitter end surfaces 203 and 204 define resonator end surfaces. The Y-direction may be referred to as a resonator direction of the light emitter 20.

The light emitter 20 has, for example, a mesa structure. As viewed in the Y-direction, the light emitter 20 is trapezoidal (ridged) and projects from the substrate main surface 101. The light emitter side surface 205 is inclined toward the contact layer connection surface 201 with respect to the substrate side surface 105 in a direction in which the substrate side surface 105 faces. The light emitter side surface 206 is inclined toward the contact layer connection surface 201 with respect to the substrate side surface 106 in a direction in which the substrate side surface 106 faces. As viewed in the Y-direction, the light emitter 20 is trapezoidal so that the substrate connection surface 202, which is connected to the substrate main surface 101, has a smaller width than the contact layer connection surface 201.

As shown in FIG. 1, the light emitter 20 is elongated in the Y-direction. For example, the light emitter 20 has the same length in the Y-direction as the semiconductor substrate 10. Thus, the light emitter end surface 203 of the light emitter 20 is flush with the substrate side surface 103 of the semiconductor substrate 10. Also, the light emitter end surface 204 of the light emitter 20 is flush with the substrate side surface 104 of the semiconductor substrate 10.

### Contact Layer

The contact layer 60 is arranged on the contact layer connection surface 201 of the light emitter 20. The contact layer 60 includes an electrode connection surface 601, a light emitter connection surface 602, contact layer end surfaces 603 and 604, and contact layer side surfaces 605 and 606. The electrode connection surface 601 and the substrate main surface 101 face the same direction in the Z-direction. That is, the electrode connection surface 601 faces the Z-direction (first direction). The light emitter connection surface 602 faces the semiconductor substrate 10. The light emitter connection surface 602 is connected to the contact layer connection surface 201 of the light emitter 20. The contact layer end surfaces 603 and 604 are two end surfaces of the contact layer 60 in the Y-direction. The contact layer end surfaces 603 and 604 face opposite directions in the Y-direction. The contact layer side surfaces 605 and 606 are two end surfaces of the contact layer 60 in the X-direction. The contact layer side surfaces 605 and 606 and face opposite directions in the X-direction. The contact layer end surfaces 603 and 604 and the contact layer side surfaces 605 and 606 connect the electrode connection surface 601 and the light emitter connection surface 602.

As shown in FIG. 2, as viewed in the Y-direction, the contact layer 60 is trapezoidal (ridged). The contact layer side surface 605 is inclined toward the electrode connection surface 601 with respect to the substrate side surface 105 in a direction in which the substrate side surface 105 faces. In an example, the inclination angle of the contact layer side surface 605 with respect to the substrate main surface 101 is equal to the inclination angle of the light emitter side surface 205 with respect to the substrate main surface 101. The contact layer side surface 605 is, for example, flush with the light emitter side surface 205. Alternatively, the inclination angle of the contact layer side surface 605 with respect to the substrate main surface 101 may differ from the inclination angle of the light emitter side surface 205 with respect to the substrate main surface 101. The contact layer side surface 606 is inclined toward the electrode connection surface 601 with respect to the substrate side surface 106 in a direction in which the substrate side surface 106 faces. In an example, the inclination angle of the contact layer side surface 606 with respect to the substrate main surface 101 is equal to the inclination angle of the light emitter side surface 206 with respect to the substrate main surface 101. The contact layer side surface 606 is, for example, flush with the light emitter side surface 206. Thus, the width of the light emitter connection surface 602 in the X-direction, which is in contact with the contact layer connection surface 201 of the light emitter 20, is equal to the width of the contact layer connection surface 201 in the X-direction. The inclination angle of the contact layer side surface 606 with respect to the substrate main surface 101 may differ from the inclination angle of the light emitter side surface 206 with respect to the substrate main surface 101. As viewed in the Y-direction, the contact layer 60 is trapezoidal so that the electrode connection surface 601 has a width WC1 that is smaller than the width of the light emitter connection surface 602, which is connected to the light emitter 20.

As shown in FIG. 1, the contact layer 60 is elongated in the Y-direction. For example, the contact layer 60 has a length in the Y-direction that is equal to the length of the light emitter 20 in the Y-direction. That is, the contact layer end surface 603 of the contact layer 60 is flush with the light emitter end surface 203 of the light emitter 20. The contact layer end surface 604 of the contact layer 60 is flush with the light emitter end surface 204 of the light emitter 20. Thus, the light emitter connection surface 602, which is in contact with the contact layer connection surface 201 of the light emitter 20, is equal in length in the Y-direction to the contact layer connection surface 201.

The contact layer 60 is arranged between the light emitter 20 and the first electrode 81 in the Z-direction. The contact layer 60 is electrically connected to the light emitter 20 and the first electrode 81. The contact layer 60 electrically connects the first electrode 81 and the light emitter 20.

The contact layer 60 includes, for example, a p-type semiconductor material having GaAs. The contact layer 60 includes, for example, at least one of carbon (C) and zinc (Zn) as a p-type impurity. The contact layer 60 has an impurity concentration, for example, in a range of 1.0×10¹⁸ cm⁻³ to 1.0×10²⁰ cm⁻³.

As shown in FIGS. 1 and 2, as viewed in the Z-direction, the electrode connection surface 601 is, for example, rectangular and elongated in the Y-direction. The width WC1 of the electrode connection surface 601 in the X-direction (third direction) is, for example, constant.

The contact layer 60 has a thickness TC1 in the Z-direction (first direction) that is greater than or equal to 2 μm. The thickness TC1 refers to a film thickness of the contact layer 60. In an example, the thickness TC1 of the contact layer 60 is less than or equal to 10 μm. The thickness TC1 of the contact layer 60 may be greater than 10 μm. The thickness TC1 of the contact layer 60 may be greater than a thickness of a second p-type cladding layer 37 in the Z-direction. The thickness TC1 of the contact layer 60 may be less than or equal to the thickness of the second p-type cladding layer 37 in the Z-direction.

### Insulation Film

The insulation film 70 includes two side covering portions 71 and 72 covering two side surfaces of the light emitter 20 in the X-direction (third direction) and two side surfaces of the contact layer 60 in the third direction. The insulation film 70 further includes two contact layer covering portions 73 and 74 covering two end regions of the electrode connection surface 601 in the third direction. The insulation film 70 may further include, for example, substrate covering portions 75 and 76 covering the substrate main surface 101 of the semiconductor substrate 10.

The side covering portion 71 covers the light emitter side surface 205 of the light emitter 20 and the contact layer side surface 605 of the contact layer 60. The side covering portion 72 covers the light emitter side surface 206 of the light emitter 20 and the contact layer side surface 606 of the contact layer 60. The side covering portion 71 is connected to the contact layer covering portion 73. The side covering portion 71 is also connected to the substrate covering portion 75. The side covering portion 72 is connected to the contact layer covering portion 74. The side covering portion 72 is also connected to the substrate covering portion 76. The insulation film 70 includes, for example, silicon nitride (SiN) or silicon oxide (SiO₂).

The insulation film 70 has a first opening 77X (opening) exposing a portion of the electrode connection surface 601. The first opening 77X is defined by the contact layer covering portions 73 and 74. More specifically, the first opening 77X corresponds to a space between an end of the contact layer covering portion 74 in the X-direction and an end of the contact layer covering portion 73 in a direction opposite to the X-direction.

### Contact Layer Covering Portion

The two contact layer covering portions 73 and 74 cover the two end regions of the electrode connection surface 601 in the X-direction (third direction). The contact layer covering portion 73 covers the end region of the electrode connection surface 601 in the X-direction. The contact layer covering portion 73 extends along the end of the electrode connection surface 601 in the X-direction. The contact layer covering portion 74 covers the end region of the electrode connection surface 601 in a direction opposite to the X-direction. The contact layer covering portion 74 extends along the end of the electrode connection surface 601 in the direction opposite to the X-direction. As viewed in the Z-direction, the contact layer covering portions 73 and 74 are each rectangular and elongated in the Y-direction. For example, the contact layer covering portions 73 and 74 each have a length in the Y-direction that is equal to the length of the electrode connection surface 601 in the Y-direction.

The contact layer covering portion 73 has a width WI1 in the X-direction that is, for example, constant in the Y-direction. The contact layer covering portion 74 has a width WI2 in the X-direction that is, for example, constant in the Y-direction. The two contact layer covering portions 73 and 74 are, for example, equal in width in the X-direction (third direction). That is, the width WI1 of the contact layer covering portion 73 may be equal to the width WI2 of the contact layer covering portion 74. The width WI1 of the contact layer covering portion 73 may differ from the width WI2 of the contact layer covering portion 74.

The ratio of the widths WI1 and WI2 of the contact layer covering portions 73 and 74 in the X-direction to the width WC1 of the electrode connection surface 601 in the X-direction is referred to as an insulation coverage. In other words, the insulation coverage is a ratio (%) of the sum of the width WI1 of the contact layer covering portion 73 and the width WI2 of the contact layer covering portion 74 to the width WC1 of the electrode connection surface 601. The insulation coverage is less than or equal to 10%. The insulation coverage is, for example, greater than 0%.

### First Electrode

The first electrode 81 is electrically connected to the electrode connection surface 601, which is exposed from the first opening 77X in the insulation film 70. The first electrode 81 covers the end of the insulation film 70 defining the first opening 77X.

The first electrode 81 may be arranged on an upper surface 701 of the insulation film 70 that covers the electrode connection surface 601 of the contact layer 60. In other words, the first electrode 81 may include a portion covering the contact layer covering portions 73 and 74. The first electrode 81 may include insulation film covering portions 83 and 84 in the two end regions of the first electrode 81 in the third direction. The insulation film covering portion 83 is located in an end region of the first electrode 81 in the X-direction. The insulation film covering portion 83 covers an end surface of the contact layer covering portion 73 in the Z-direction. The contact layer covering portion 73 is sandwiched between the insulation film covering portion 83 and the contact layer 60 in the Z-direction. The insulation film covering portion 84 is located in the end region of the first electrode 81 in a direction opposite to the X-direction. The insulation film covering portion 84 covers an end surface of the contact layer covering portion 74 in the Z-direction. The contact layer covering portion 74 is sandwiched between the insulation film covering portion 84 and the contact layer 60 in the Z-direction.

The first electrode 81 may include multiple electrode layers. In an example, the first electrode 81 includes a first electrode layer and a second electrode layer. The first electrode layer and the second electrode layer are stacked in this order from the side of the electrode connection surface 601. The first electrode layer includes, for example, titanium (Ti)/gold (Au). The second electrode layer includes, for example, a plating layer including Au.

### Second Electrode

The second electrode 82 is arranged on the substrate back surface 102 of the semiconductor substrate 10. The second electrode 82 covers, for example, the entirety of the substrate back surface 102. The second electrode 82 is electrically connected to the semiconductor substrate 10.

The second electrode 82 may include multiple electrode layers. The second electrode 82 may include at least one of a nickel (Ni) layer, a gold-germanium (AuGe) alloy layer, a Ti layer, and an Au layer. In an example, the second electrode 82 may include a Ni layer, an AuGe layer, a Ti layer, and an Au layer that are sequentially stacked from the substrate back surface 102.

### Exemplary Structure of Light Emitter

As shown in FIG. 2, the light emitter 20 includes a light emitting unit 21 formed on the substrate main surface 101 of the semiconductor substrate 10. The light emitting unit 21 combines holes and electrons to generate light. The light emitter 20 includes, for example, three light emitting units 21. The light emitter 20 may include at least one light emitting unit 21. That is, the number of light emitting units 21 may be one, two, four, or more.

The light emitter 20 has a width WL1 in the X-direction (third direction) that is in a range of, for example, 200 μm to 400 μm. The width WL1 of the light emitter 20 is, for example, an average width of the light emitter 20 in the X-direction. When the light emitter 20 includes three light emitting units 21, the width WL1 of the light emitter 20 is the width of the central one of the light emitting units 21 in the X-direction. The width WL1 of the light emitter 20 is, for example, 225 μm. The width WL1 of the light emitter 20 is not limited to 225 μm. The width WL1 of the light emitter 20 may be less than 200 μm or may be greater than 400 μm.

The light emitter 20 includes, for example, tunnel layers 22 located between adjacent ones of the light emitting units 21. The tunnel layers 22 generate tunnel current due to the tunnel effect and supply the tunnel current to the light emitting units 21. In an example, the light emitter 20 includes two tunnel layers 22. Each tunnel layer 22 is located between two of the light emitting units 21 located adjacent to each other.

### Light Emitting Unit

FIG. 3 is a diagram showing the structure of the light emitting unit 21.

The light emitting unit 21 includes an active layer 31 and an n-type semiconductor layer 32 and a p-type semiconductor layer 33 that sandwich the active layer 31 in the thickness-wise direction of the active layer 31. The n-type semiconductor layer 32 is located at a side of the active layer 31 close to the semiconductor substrate 10 shown in FIGS. 1 and 2. The p-type semiconductor layer 33 is located at a side opposite to the n-type semiconductor layer 32 with respect to the active layer 31, that is, close to the first electrode 81 shown in FIGS. 1 and 2. In other words, the light emitting unit 21 has a stack structure including the n-type semiconductor layer 32, the active layer 31, and the p-type semiconductor layer 33 that are sequentially stacked from the side of the semiconductor substrate 10.

n-Type Semiconductor Layer

The n-type semiconductor layer 32 includes aluminum-gallium-arsenic (AlGaAs).

The n-type semiconductor layer 32 includes, for example, at least one of Si, Te, and Se as an n-type impurity. The n-type semiconductor layer 32 has an impurity concentration that is, for example, in a range of 1.0×10¹⁷ cm⁻³ to 1.0×10¹⁹ cm⁻³.

The n-type semiconductor layer 32 includes a first n-type cladding layer 34 and a second n-type cladding layer 35. The first n-type cladding layer 34 is located adjacent to the active layer 31. The second n-type cladding layer 35 and the active layer 31 are located at opposite sides of the first n-type cladding layer 34. In other words, the n-type semiconductor layer 32 includes the first n-type cladding layer 34, which is located adjacent to the active layer 31, and the second n-type cladding layer 35, which is located at a side opposite to the active layer 31 with respect to the first n-type cladding layer 34. In other words, the n-type semiconductor layer 32 includes the first n-type cladding layer 34 and the second n-type cladding layer 35 stacked in this order from the side of the active layer 31.

The impurity concentration of the second n-type cladding layer 35 may differ from the impurity concentration of the first n-type cladding layer 34. More specifically, the impurity concentration of the second n-type cladding layer 35 may be greater than the impurity concentration of the first n-type cladding layer 34. The impurity concentration of the second n-type cladding layer 35 may be equal to the impurity concentration of the first n-type cladding layer 34. The impurity concentration of the second n-type cladding layer 35 may be less than the impurity concentration of the first n-type cladding layer 34.

p-Type Semiconductor Layer

The p-type semiconductor layer 33 includes AlGaAs. The p-type semiconductor layer 33 includes, for example, carbon as a p-type impurity. The p-type semiconductor layer 33 has an impurity concentration that is, for example, in a range of 1.0×10¹⁷ cm⁻³ to 1.0×10¹⁹ cm⁻³.

The p-type semiconductor layer 33 includes a first p-type cladding layer 36 and the second p-type cladding layer 37. The first p-type cladding layer 36 is located adjacent to the active layer 31. The second p-type cladding layer 37 and the active layer 31 are located at opposite sides of the first p-type cladding layer 36. In other words, the p-type semiconductor layer 33 includes the first p-type cladding layer 36, which is located adjacent to the active layer 31, and the second p-type cladding layer 37, which is located at a side opposite from the active layer 31 with respect to the first p-type cladding layer 36. In other words, the p-type semiconductor layer 33 includes the first p-type cladding layer 36 and the second p-type cladding layer 37 stacked in this order from the side of the active layer 31.

The impurity concentration of the second p-type cladding layer 37 may differ from the impurity concentration of the first p-type cladding layer 36. More specifically, the impurity concentration of the second p-type cladding layer 37 may be greater than the impurity concentration of the first p-type cladding layer 36. The impurity concentration of the second p-type cladding layer 37 may be equal to the impurity concentration of the first p-type cladding layer 36. The impurity concentration of the second p-type cladding layer 37 may be less than the impurity concentration of the first p-type cladding layer 36.

### Active Layer

FIG. 4 is a diagram showing an exemplary structure of the active layer 31.

The active layer 31 has a multiple quantum well structure that includes a barrier layer 41, a first well layer 42, and a second well layer 43. The active layer 31 includes, for example, the barrier layer 41, the first well layer 42, the second well layer 43, a first guide layer 44, and a second guide layer 45.

The first well layer 42 and the second well layer 43 are located at opposite sides of the barrier layer 41. The first well layer 42 is located adjacent to the barrier layer 41 at a side of the barrier layer 41 close to the n-type semiconductor layer 32 shown in FIG. 3. The second well layer 43 and the first well layer 42 are located at opposite sides of the barrier layer 41. In other words, the active layer 31 includes the first well layer 42, the barrier layer 41, and the second well layer 43 that are stacked in this order from the n-type semiconductor layer 32 (the first n-type cladding layer 34) shown in FIG. 3.

The first guide layer 44 is located adjacent to the first well layer 42. The first guide layer 44 and the barrier layer 41 are located at opposite sides of the first well layer 42. The second guide layer 45 is located adjacent to the second well layer 43. The second guide layer 45 and the barrier layer 41 are located at opposite sides of the second well layer 43. In other words, the first guide layer 44 and the second guide layer 45 sandwich the first well layer 42, the barrier layer 41, and the second well layer 43. In other words, the active layer 31 includes the first guide layer 44, the first well layer 42, the barrier layer 41, the second well layer 43, and the second guide layer 45 that are stacked in this order from the n-type semiconductor layer 32 (the first n-type cladding layer 34) shown in FIG. 3.

### Tunnel Layer

FIG. 5 is a diagram showing an exemplary structure of the tunnel layers 22.

The tunnel layer 22 includes a p-type tunnel layer 51 and an n-type tunnel layer 52. The p-type tunnel layer 51 is located adjacent to the p-type semiconductor layer 33 (the second p-type cladding layer 37) shown in FIG. 3. The n-type tunnel layer 52 is located adjacent to the n-type semiconductor layer 32 (the second n-type cladding layer 35) shown in FIG. 3. Thus, the p-type tunnel layer 51 and the n-type tunnel layer 52 are stacked in this order from the side of the semiconductor substrate 10 shown in FIGS. 1 and 2. Each tunnel layer 22 is arranged between the light emitting units 21 so that the p-type tunnel layer 51 is electrically connected to the p-type semiconductor layer 33 shown in FIG. 3 and the n-type tunnel layer 52 is electrically connected to the n-type semiconductor layer 32 shown in FIG. 3.

The p-type tunnel layer 51 includes GaAs. The p-type tunnel layer 51 includes, for example, carbon as a p-type impurity. The impurity concentration of the p-type tunnel layer 51 differs from the impurity concentration of the p-type semiconductor layer 33. The impurity concentration of in the p-type tunnel layer 51 is higher than the impurity concentration of the p-type semiconductor layer 33.

The n-type tunnel layer 52 includes GaAs. The n-type tunnel layer 52 includes, for example, at least one of Si, Te, and Se as an n-type impurity. The impurity concentration of the n-type tunnel layer 52 differs from the impurity concentration of the n-type semiconductor layer 32. The impurity concentration of the n-type tunnel layer 52 is higher than the impurity concentration of the n-type semiconductor layer 32.

### Operation of Embodiment

The operation of the semiconductor laser device 1A of the present embodiment will now be described.

In the present embodiment, the semiconductor laser device 1A includes the semiconductor substrate 10 including the substrate main surface 101 and the substrate back surface 102 that face in opposite directions in the Z-direction (first direction), which is orthogonal to the substrate main surface 101. The semiconductor laser device 1A further includes the light emitter 20 projecting from the substrate main surface 101 in the Z-direction and including the contact layer connection surface 201, which faces the Z-direction, and the light emitter end surfaces 203 and 204, which are two end surfaces in the Z-direction orthogonal to the Y-direction (second direction). The semiconductor laser device 1A further includes the contact layer 60 arranged on the contact layer connection surface 201 and including the electrode connection surface 601 facing in the Z-direction. The semiconductor laser device 1A further includes the insulation film 70. The insulation film 70 includes two side covering portions 71 and 72 that cover two side surfaces of the light emitter 20 in the X-direction (third direction), which is orthogonal to the Z-direction and the Y-direction, and two side surfaces of the contact layer 60 in the X-direction. The insulation film 70 further includes two contact layer covering portions 73 and 74 covering two end regions of the electrode connection surface 601 in the X-direction. The insulation film 70 has the first opening 77X, which is defined by the two contact layer covering portions 73 and 74 and partially exposes the electrode connection surface 601. The semiconductor laser device 1A includes the first electrode 81 (electrode), which is electrically connected to the electrode connection surface 601 exposed from the first opening 77X. The light emitter 20 emits laser light L1 from the light emitter end surfaces 203 and 204.

In the active layer 31 of the semiconductor laser device 1A, electrons from the n-type semiconductor layer 32 recombine with holes from the p-type semiconductor layer 33. As a result, light is generated in the active layer 31. As the light generated in the active layer 31 repeatedly undergoes stimulated emission between the light emitter end surfaces 203 and 204 of the light emitter 20 defining end surfaces of the active layer 31 and serving as the resonator end surfaces, the light is resonantly amplified. A portion of the amplified light is emitted as laser light L1 from the light emitter end surface 203 of the light emitter 20, which is one of the resonator end surfaces.

FIG. 6 is a schematic diagram of the laser light L1 emitted from the light emitter 20. In FIG. 6, the laser light L1 is emitted from a single light emitting unit 21.

As shown in FIG. 6, on the light emitter end surface 203 of the light emitter 20, the laser light L1 emitted from the light emitter 20 has the form of an ellipse that is elongated in a direction (X-direction) parallel to the active layer 31. At a location separated from the light emitter end surface 203 of the light emitter 20, the laser light L1 has the form of an ellipse that is elongated in a direction (Z-direction) perpendicular to the active layer 31.

The emission pattern property (divergence) of the laser light L1 emitted from the light emitter end surface 203 of the light emitter 20 is expressed as an angle of far field pattern (FFP). The FFP of the laser light L1 is indicated by a first angle θh (degrees) in a direction parallel to the active layer 31 and a second angle θv (degrees) in the thickness-wise direction of the active layer 31. The first angle θh and the second angle θv correspond to angles at which the intensity of the laser light L1 is at its Full Width Half maximum (FWH).

The semiconductor laser device 1A is used in, for example, a laser system such as a Light Detection and Ranging, or a Laser Imaging Detection and Ranging (LiDAR), which is an example of three dimensional distance measurement, and two dimensional distance measurement. In such a laser system, the laser light L1 emitted from the semiconductor laser device 1A is coupled to a lens. When a scan-type measurement process involves scanning the laser light L1 to detect the distance, the direction, and the property of a subject being measured, the laser light L1 coupled to the lens is, for example, parallel light. In this case, it is desirable that the intensity of the laser light L1 be uniform in the range of a spot diameter. When a flash-type measurement process involves measuring the surrounding area without scanning the laser light L1, the laser light L1 coupled to the lens is, for example, convergent light. In this case, it is desirable that the laser light L1 be uniformly irradiated in the irradiation range. As described above, in each of the scan-type measurement process and the flash-type measurement process, it is desirable that the intensity of emitted light be uniform in the range of the width WL1 of the light emitter 20 in the X-direction.

In such a laser system, if a side peak differing from a center peak is produced in a position of FFP shifted from the center peak in the X-direction, the laser light L1 having passed through the lens may contain noise light. If the laser light L1 contains noise light, the measurement accuracy of the laser system may be decreased.

In the semiconductor laser device 1A of the present embodiment, the insulation coverage, which is the ratio of the widths WC1 and WC2 of the two contact layer covering portions 73 and 74 in the X-direction to the width WC1 of the electrode connection surface 601 in the X-direction, is set to be less than or equal to 10%. The thickness TC1 of the contact layer 60 in the Z-direction is greater than or equal to 2 μm. This allows a current supplied to the contact layer 60 through the first electrode 81 to readily travel to the two ends of the contact layer 60 in the X-direction. Thus, the current flowing through the contact layer 60 is supplied to the regions of the two ends of the light emitter 20 in the X-direction. Therefore, the light emitter 20 generates light over the entire region in the X-direction. This increases the relative intensity of emitted light in the X-direction from the central portion of the light emitter 20 to the end regions. A side peak is less likely to be produced in the FFP in the X-direction.

### Experimental Examples

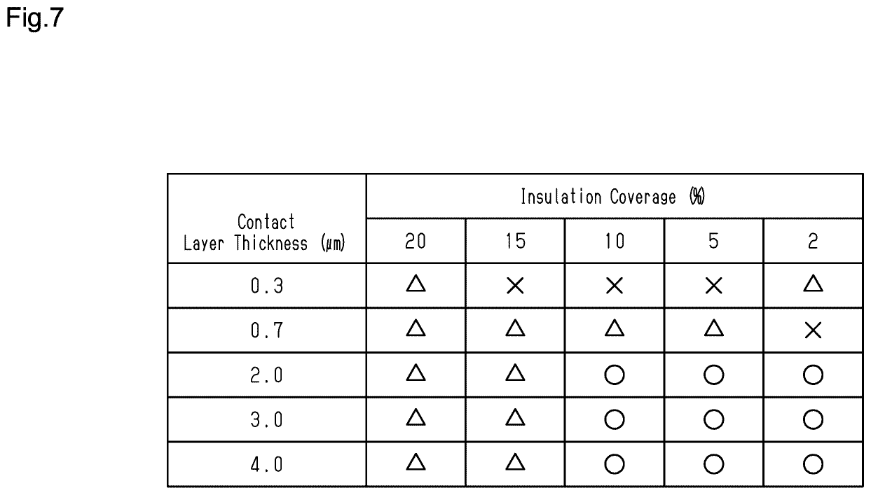

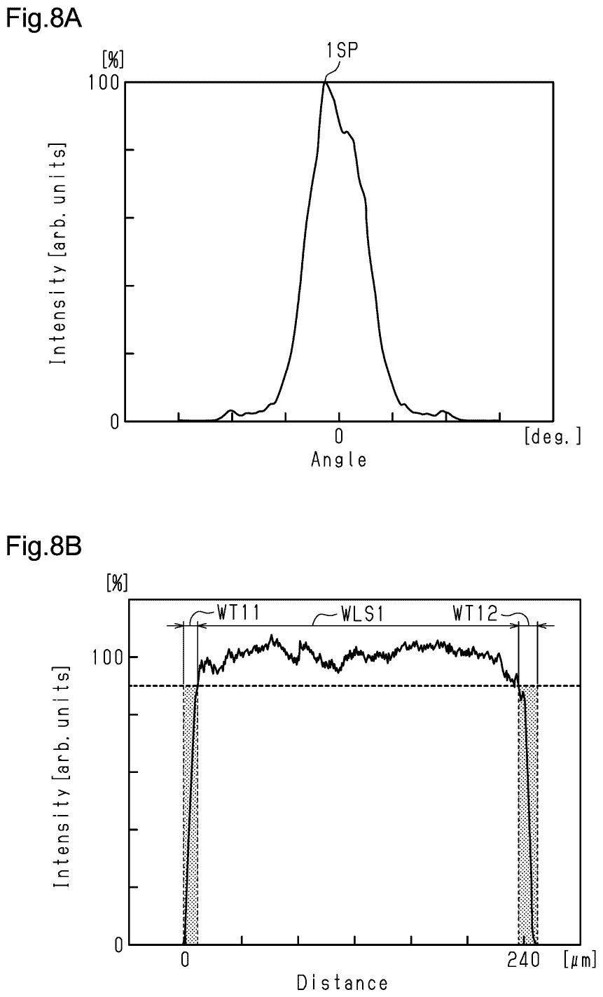

Experimental examples of a semiconductor laser device will now be described. FIG. 7 is a diagram showing the relationships of the insulation coverage, the thickness TC1 of the contact layer 60, and the state of laser light 1L in experimental examples of a semiconductor laser device. FIGS. 8A to 11A are diagrams showing a far field pattern of the semiconductor laser device in the experimental examples. FIGS. 8B to 11B are diagrams showing a near field pattern of the semiconductor laser device in the experimental examples. In FIGS. 8A to 11A, the horizontal axis represents an angle centered on a front surface of the light emitter 20. The vertical axis represents the intensity of emitted light (output of laser light L1). In FIGS. 8B to 11B, the horizontal axis represents distance from an end of the light emitter 20 in the X-direction (third direction). The vertical axis represents the intensity of emitted light (output of laser light L1).

In the semiconductor laser device of each experimental example, as the insulation coverage and the thickness TC1 of the contact layer 60 are changed, an FFP and a near field pattern (NFP) are measured in the X-direction.

NFP indicates the intensity of the laser light L1 in the vicinity of the light emitter end surface 203 of the light emitter 20. NFP may be used as an index for determining whether the intensity of light emitted from the light emitter 20 is uniform. In each experimental example shown in FIG. 7, the intensity of emitted light in NFP in the center of the light emitter 20 in the X-direction was used as a reference (100%). Alternatively, an average value of the intensity of light emitted from the light emitter 20 in the X-direction may be used as a reference. In each of the two end regions of the light emitter 20 in the X-direction, the distance in the X-direction where the intensity of light emitted in NFP ranges from a predetermined value (e.g., 90%) to 0%, is referred to as “light emission flare width”. As the light emission flare width becomes smaller, the light emitter 20 operates and emits light up to the vicinity of its ends in the X-direction. Thus, in the light emission width of the laser light L1 emitted from the light emitter 20, the intensity of emitted light is uniform over the entirety of the light emitter 20 in the X-direction.

As shown in FIG. 7, in the experiments, FFP and NFP were measured when the insulation coverage was 20%, 15%, 10%, 5%, and 2%, and the thickness TC1 of the contact layer 60 was changed to 0.3 μm, 0.7 μm, 2.0 μm, 3.0 μm, and 4.0 μm. In each experimental example, the width WL1 of the light emitter 20 in the X-direction is 225 μm. In each experimental example, in FFP, the maximum intensity of emitted light was used as a reference (100%). With reference to FFP, whether a side peak was present was determined. With reference to NFP, the light emission flare width was measured.

In FIG. 7, “∘, circle” is given to a combination of the insulation coverage and the thickness TC1 of the contact layer 60 when both FFP does not have a side peak, and the light emission flare width is less than 10 μm at each of the two end regions of the light emitter 20 in the X-direction. In FIG. 7, “Δ, triangle” is given to a combination of the insulation coverage and the thickness TC1 of the contact layer 60 when either FFP does not have a side peak, or the light emission flare width is less than 10 μm at each of the two end regions of the light emitter 20 in the X-direction. In FIG. 7, “×, cross” is given to a combination of the insulation coverage and the thickness TC1 of the contact layer 60 when both FFP has a side peak and the light emission flare width is greater than or equal to 10 μm at each of the two end regions of the light emitter 20 in the X-direction.

Referring to FIG. 7, when both the insulation coverage is less than or equal to 10% and the thickness TC1 of the contact layer 60 is greater than or equal to 2.0 μm, the FFP does not have a side peak, and the light emission flare width is less than 10 μm at each of the two end regions of the light emitter 20 in the X-direction.

FIG. 8A is a diagram showing a measurement result of FFP of the semiconductor laser device in the X-direction when the insulation coverage is 10% and the thickness TC1 of the contact layer 60 is 2.0 μm. FIG. 8B is a diagram showing a measurement result of NFP of the semiconductor laser device in the X-direction when the insulation coverage is 10% and the thickness TC1 of the contact layer 60 is 2.0 μm.

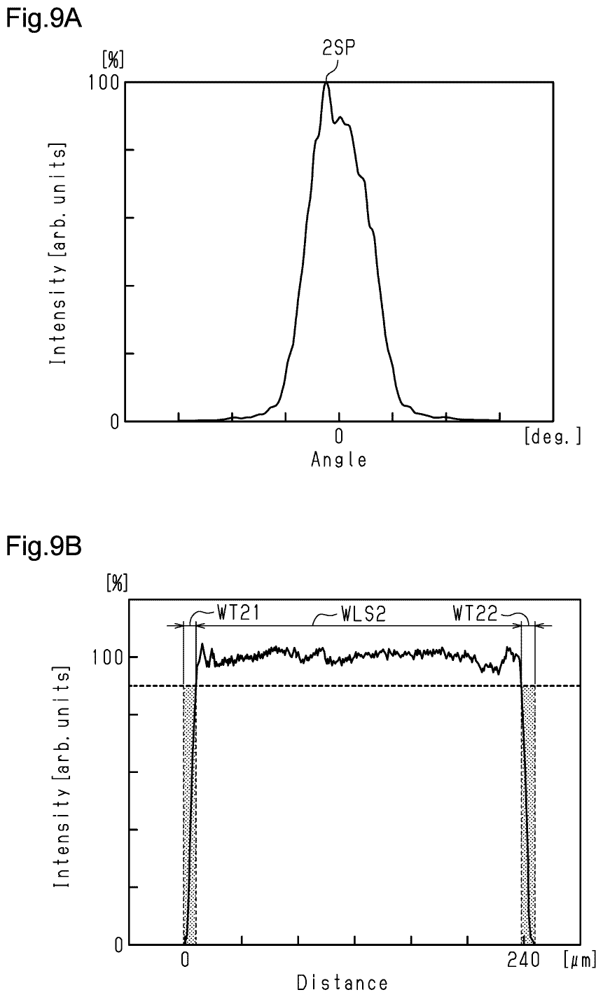

FIG. 9A is a diagram showing a measurement result of FFP of the semiconductor laser device in the X-direction when the insulation coverage is 2% and the thickness TC1 of the contact layer 60 is 4.0 μm. FIG. 9B is a diagram showing a measurement result of NFP of the semiconductor laser device in the X-direction when the insulation coverage is 2% and the thickness TC1 of the contact layer 60 is 4.0 μm.

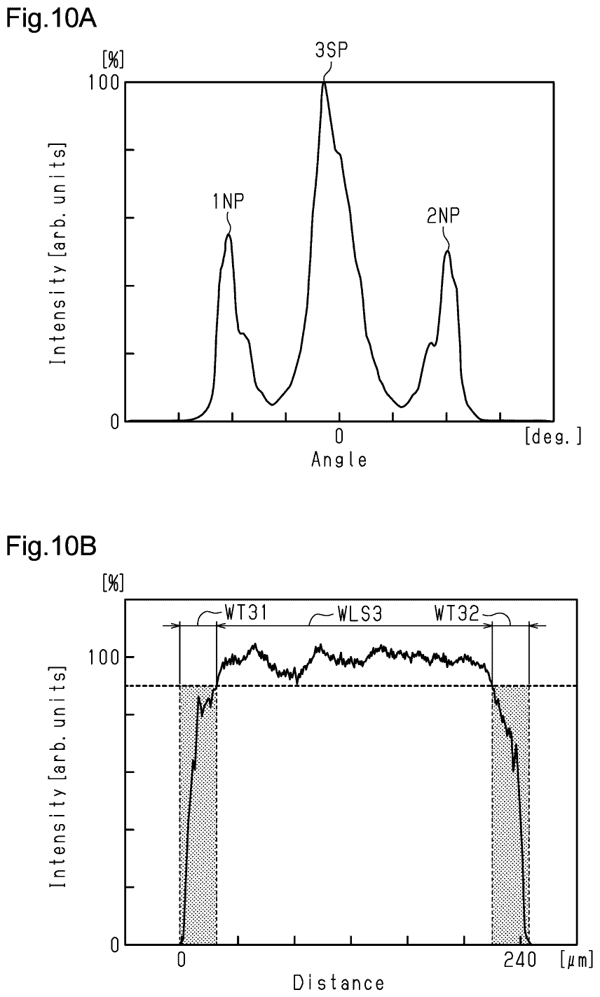

FIG. 10A is a diagram showing a measurement result of FFP of the semiconductor laser device in the X-direction when the insulation coverage is 10% and the thickness TC1 of the contact layer 60 is 0.3 μm. FIG. 10B is a diagram showing a measurement result of NFP of the semiconductor laser device in the X-direction when the insulation coverage is 10% and the thickness TC1 of the contact layer 60 is 0.3 μm.

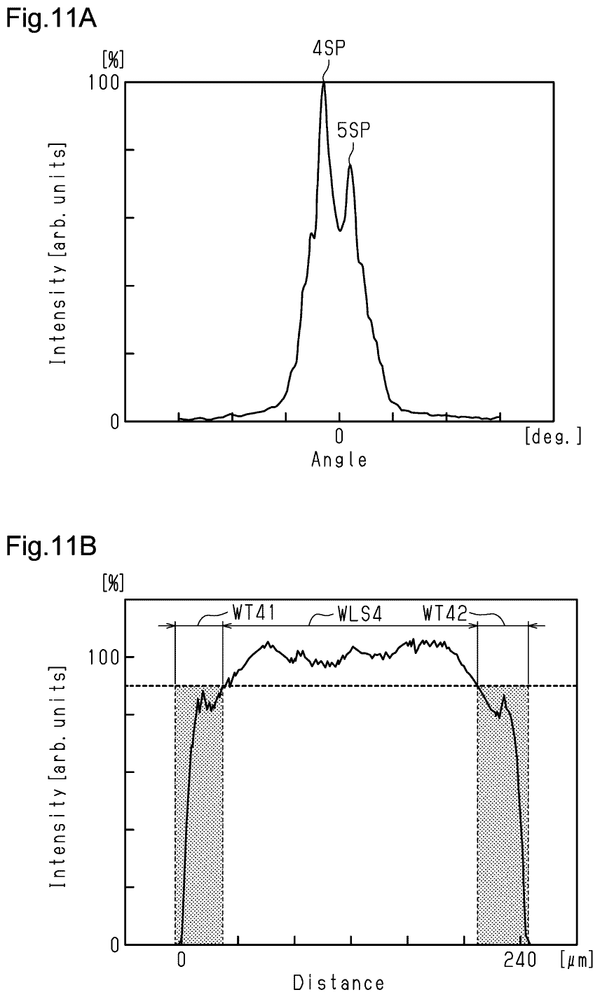

FIG. 11A is a diagram showing a measurement result of FFP of the semiconductor laser device in the X-direction when the insulation coverage is 20% and the thickness TC1 of the contact layer 60 is 2.0 μm. FIG. 11B is a diagram showing a measurement result of NFP of the semiconductor laser device in the X-direction when the insulation coverage is 20% and the thickness TC1 of the contact layer 60 is 2.0 μm.

In FIGS. 8A to 11A, the horizontal axis represents an angle centered on the front surface of the light emitter 20. In FIGS. 8A to 11A, the vertical axis represents the intensity of emitted light. In FIGS. 8B to 11B, the horizontal axis represents the distance from one end of the light emitter 20 in the X-direction (third direction). In an example, the end of the light emitter 20 located in a direction opposite to the X-direction is 0 μm. In this case, the horizontal axis represents the distance in the X-direction from the end of the light emitter 20 in the direction opposite to the X-direction. In FIGS. 8B to 11B, the vertical axis represents the intensity of emitted light (output of laser light). In FIGS. 8B to 11B, a section corresponding to the light emission flare width is indicated by dots. In FIGS. 8B to 11B, widths WLS1 to WLS4 indicate the width, in the X-direction, of the region in which the intensity of light emitted from the light emitter 20 of the semiconductor laser device in each experimental example is greater than or equal to 90%.

FIG. 8A shows that when the semiconductor laser device has the insulation coverage of 10% and the thickness TC1 of the contact layer 60 of 2.0 μm, the laser light L1 has a single peak 1SP in the center. FIG. 8B shows that in the same semiconductor laser device, the light emission flare widths WT11 and WT12 are each approximately 9 μm.

FIG. 9A shows that when the semiconductor laser device has the insulation coverage of 2% and the thickness TC1 of the contact layer 60 of 4.0 μm, the laser light L1 has a single peak 2SP in the center. FIG. 9B shows that in the same semiconductor laser device, the light emission flare widths WT21 and WT22 are each approximately 8 μm.

FIG. 10A shows that when the semiconductor laser device has the insulation coverage of 10% and the thickness TC1 of the contact layer 60 of 0.3 μm, the laser light L1 has a peak 3SP in the center and side peaks 1NP and 2NP at opposite sides of the peak 3SP. FIG. 10B shows that in the same semiconductor laser device, the light emission flare widths WT31 and WT32 are each approximately 30 μm.

FIG. 11A shows that when the semiconductor laser device has the insulation coverage of 20% and the thickness TC1 of the contact layer 60 of 2.0 μm, the laser light L1 has a peak 4SP in the center and a peak 5SP shifted from the peak 4SP. FIG. 11B shows that in the same semiconductor laser device, the light emission flare widths WT41 and WT42 are each approximately 35 μm. The peak 5SP is present at an angle close to the center of the light emitter 20 (i.e., angle close to 0°. It is considered, in the semiconductor laser device in this experimental example, that the FFP does not have a side peak and the light emission flare width is greater than or equal to 10 μm at each of the two end regions of the light emitter 20 in the X-direction. Hence, in FIG. 7, “Δ, triangle” is given to the combination of the insulation coverage of 20% and the thickness TC1 of the contact layer 60 of 2.0 μm.

Comparison of FIG. 8B and FIG. 10B shows that the light emission flare widths WT11 and WT12 of the semiconductor laser device having the insulation coverage of 10% and the thickness TC1 of the contact layer 60 of 2.0 μm are smaller than the light emission flare widths WT31 and WT32 of the semiconductor laser device having the insulation coverage of 10% and the thickness TC1 of the contact layer 60 of 0.3 μm. The width WLS1 is larger than the width WLS3. Thus, the light emitter 20 of the semiconductor laser device having the insulation coverage of 10% and the thickness TC1 of the contact layer 60 of 2.0 μm operates and emits light up to the vicinity of its ends in the X-direction as compared to the light emitter 20 of the semiconductor laser device having the insulation coverage of 10% and the thickness TC1 of the contact layer 60 of 0.3 μm. Therefore, in the semiconductor laser device having the insulation coverage of 10% and the thickness TC1 of the contact layer 60 of 2.0 μm, the intensity of the laser light L1 is more uniform in the X-direction over the entirety of the light emitter 20 than in the semiconductor laser device having the insulation coverage of 10% and the thickness TC1 of the contact layer 60 of 0.3 μm.

Comparison of FIG. 8B and FIG. 11B shows that the light emission flare widths WT11 and WT12 of the semiconductor laser device having the insulation coverage of 10% and the thickness TC1 of the contact layer 60 of 2.0 μm are smaller than the light emission flare widths WT41 and WT42 of the semiconductor laser device having the insulation coverage of 20% and the thickness TC1 of the contact layer 60 of 2.0 μm. The width WLS1 is larger than the width WLS4. Thus, the light emitter 20 of the semiconductor laser device having the insulation coverage of 10% and the thickness TC1 of the contact layer 60 of 2.0 μm operates and emits light up to the vicinity of its ends in the X-direction as compared to the light emitter 20 of the semiconductor laser device having the insulation coverage of 20% and the thickness TC1 of the contact layer 60 of 2.0 μm. Therefore, in the semiconductor laser device having the insulation coverage of 10% and the thickness TC1 of the contact layer 60 of 2.0 μm, the intensity of the laser light L1 is more uniform in the X-direction over the entirety of the light emitter 20 than in the semiconductor laser device having the insulation coverage of 20% and the thickness TC1 of the contact layer 60 of 2.0 μm.

Comparison of FIG. 9B and FIG. 10B shows that the light emission flare widths WT21 and WT22 of the semiconductor laser device having the insulation coverage of 2% and the thickness TC1 of the contact layer 60 of 4.0 μm are smaller than the light emission flare widths WT31 and WT32 of the semiconductor laser device having the insulation coverage of 10% and the thickness TC1 of the contact layer 60 of 0.3 μm. The width WLS2 is larger than the width WLS3. Thus, the light emitter 20 of the semiconductor laser device having the insulation coverage of 2% and the thickness TC1 of the contact layer 60 of 4.0 μm operates and emits light up to the vicinity of its ends in the X-direction as compared to the light emitter 20 of the semiconductor laser device having the insulation coverage of 10% and the thickness TC1 of the contact layer 60 of 0.3 μm. Therefore, in the semiconductor laser device having the insulation coverage of 2% and the thickness TC1 of the contact layer 60 of 4.0 μm, the intensity of the laser light L1 is more uniform in the X-direction over the entirety of the light emitter 20 than in the semiconductor laser device having the insulation coverage of 10% and the thickness TC1 of the contact layer 60 of 0.3 μm.

Comparison of FIG. 9B and FIG. 11B shows that the light emission flare widths WT21 and WT22 of the semiconductor laser device having the insulation coverage of 2% and the thickness TC1 of the contact layer 60 of 4.0 μm are smaller than the light emission flare widths WT41 and WT42 of the semiconductor laser device having the insulation coverage of 20% and the thickness TC1 of the contact layer 60 of 2.0 μm. The width WLS2 is larger than the width WLS4. Thus, the light emitter 20 of the semiconductor laser device having the insulation coverage of 2% and the thickness TC1 of the contact layer 60 of 4.0 μm operates and emits light up to the vicinity of its ends in the X-direction as compared to the light emitter 20 of the semiconductor laser device having the insulation coverage of 20% and the thickness TC1 of the contact layer 60 of 2.0 μm. Therefore, in the semiconductor laser device having the insulation coverage of 2% and the thickness TC1 of the contact layer 60 of 4.0 μm, the intensity of the laser light L1 is more uniform in the X-direction over the entirety of the light emitter 20 than in the semiconductor laser device having the insulation coverage of 20% and the thickness TC1 of the contact layer 60 of 2.0 μm.

### Effects of Embodiment

As described above, the present embodiment has the following advantages.

(1) The semiconductor laser device 1A includes the semiconductor substrate 10 including the substrate main surface 101 and the substrate back surface 102 that face in opposite directions in the Z-direction (first direction), which is orthogonal to the substrate main surface 101. The semiconductor laser device 1A further includes the light emitter 20 projecting from the substrate main surface 101 in the Z-direction and including the contact layer connection surface 201, which faces the Z-direction, and the light emitter end surfaces 203 and 204, which are two end surfaces in the Z-direction orthogonal to the Y-direction (second direction). The semiconductor laser device 1A further includes the contact layer 60 arranged on the contact layer connection surface 201 and including the electrode connection surface 601 facing in the Z-direction. The semiconductor laser device 1A further includes the insulation film 70. The insulation film 70 includes two side covering portions 71 and 72 that cover two side surfaces of the light emitter 20 in the X-direction (third direction), which is orthogonal to the Z-direction and the Y-direction, and two side surfaces of the contact layer 60 in the X-direction. The insulation film 70 further includes two contact layer covering portions 73 and 74 covering two end regions of the electrode connection surface 601 in the X-direction. The insulation film 70 has the first opening 77X, which is defined by the two contact layer covering portions 73 and 74 and partially exposes the electrode connection surface 601. The semiconductor laser device 1A includes the first electrode 81 (electrode), which is electrically connected to the electrode connection surface 601 exposed from the first opening 77X. The light emitter 20 emits the laser light L1 from one of the two light emitter end surfaces 203 and 204. The insulation coverage, which is a ratio of the widths WI1 and WI2 of the contact layer covering portions 73 and 74 in the X-direction to the width WC1 of the electrode connection surface 601 in the X-direction, is less than or equal to 10%. The thickness TC1 of the contact layer 60 in the Z-direction is greater than or equal to 2 μm.

This structure allows the current supplied to the contact layer 60 through the first electrode 81 to be supplied to the two ends of the contact layer 60 in the X-direction. Thus, the current flowing through the contact layer 60 is supplied to the regions of the two ends of the light emitter 20 in the X-direction. Therefore, the light emitter 20 generates light over the entire region in the X-direction. This increases the relative intensity of emitted light in the X-direction from the central portion of the light emitter 20 to the end regions. A side peak is less likely to be produced in the FFP in the X-direction. As a result, the intensity of emitted light is uniform in the vicinity of the end surfaces of the light emitter 20. Additionally, the laser light L1, which is emitted from the light emitter end surface 203 of the light emitter 20, is less likely to contain noise light.

(2) In the semiconductor laser device 1A of the present embodiment, the insulation coverage is greater than 0%.

With this structure, the insulation film 70 including the contact layer covering portions 73 and 74 are readily manufactured. Even when the width WC1 of the electrode connection surface 601 varies within the dimensional tolerance range, the insulation film 70 including the contact layer covering portions 73 and 74 is readily manufactured.

(3) In the semiconductor laser device 1A of the present embodiment, the thickness TC1 of the contact layer 60 in the Z-direction is less than or equal to 10 μm.

With this structure, the contact layer 60 is readily manufactured as compared to when the thickness TC1 of the contact layer 60 is greater than 10 μm.

(4) In the semiconductor laser device 1A of the present embodiment, the widths WI1 and WI2 of the two contact layer covering portions 73 and 74 in the X-direction are equal to each other.

This structure allows the current supplied to the contact layer 60 through the first electrode 81 to be transmitted to the two ends of the contact layer 60 in the X-direction.

(5) In the semiconductor laser device 1A of the present embodiment, the width WL1 of the light emitter 20 in the X-direction (third direction) is in a range of 200 μm to 400 μm.

In a conventional semiconductor laser device including a light emitter having a width of 200 μm or greater in the X-direction, even when the intensity of emitted light is uniform in the X-direction, the FFP still has a side peak. In the semiconductor laser device 1A of the present embodiment, even when the width WL1 is 200 μm or greater, the intensity of emitted light is uniform in the vicinity of the end surface of the light emitter 20. Additionally, the laser light L1, which is emitted from the light emitter end surface 203 of the light emitter 20, is less likely to contain noise light.

### MODIFIED EXAMPLES

The embodiments may be modified, for example, as follows. The embodiments described above and modified examples described below may be combined with one another as long as there is no technical inconsistency. In the following modified examples, the same reference characters are given to those elements that are the same as the corresponding elements of the above embodiments. Such elements will not be described in detail.

The structure of the semiconductor laser device 1A may be changed.

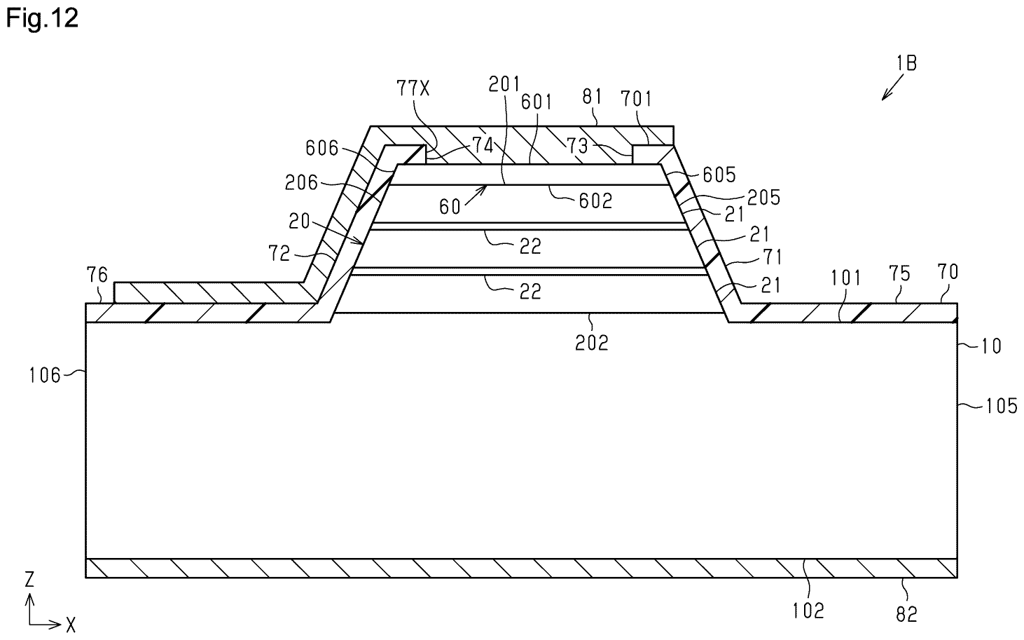

FIG. 12 is a diagram showing a modified example of a semiconductor laser device 1B

The semiconductor laser device 1B includes a first electrode 81 extending from the electrode connection surface 601 of the contact layer 60 to the substrate covering portion 76 of the insulation film 70, which covers the substrate main surface 101. The first electrode 81, which extends to the substrate main surface 101, may be connected to a pillar, a wire, or the like, to drive the semiconductor laser device 1B.

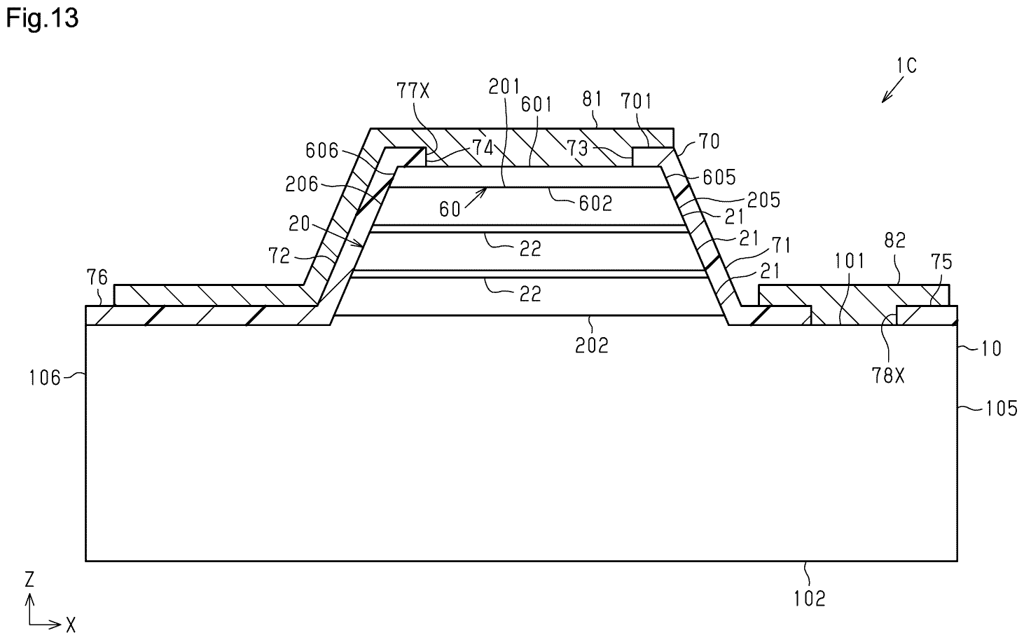

FIG. 13 is a diagram showing a modified example of a semiconductor laser device 1C.

In the same manner as the semiconductor laser device 1B shown in FIG. 12, the semiconductor laser device 1C of this modified example includes a first electrode 81 extending from the electrode connection surface 601 of the contact layer 60 to the substrate covering portion 76 of the insulation film 70, which covers the substrate main surface 101. The semiconductor laser device 1C of the modified example further includes a second opening 78X in the substrate covering portion 75 of the insulation film 70 to expose a portion of the substrate main surface 101 of the semiconductor substrate 10. The second electrode 82 is electrically connected to the semiconductor substrate 10 exposed from the second opening 78X in the insulation film 70. The light emitter 20 is connected to the substrate main surface 101 of the semiconductor substrate 10. Thus, the second electrode 82 is electrically connected to the light emitter 20 by the semiconductor substrate 10. The light emitter 20 is connected between the first electrode 81 and the second electrode 82. As described above, the semiconductor laser device 1C is driven by the first electrode 81 and the second electrode 82, which are arranged at the side of the substrate main surface 101. The first electrode 81 and the second electrode 82, which are located at the side of the substrate main surface 101, allow for wire connection and flip-chip-mounting using pillars from the same side.

In the semiconductor laser device 1C of the modified example, the first electrode 81 may be identical in shape to the first electrode 81 in the semiconductor laser device 1A of the embodiment. The shapes of the first electrode 81 and the second electrode 82 may be changed.

In the embodiment described above, the light emitter 20 includes three light emitting units 21 and two tunnel layers 22. However, the number of light emitting units 21 is not limited to three and may be any number. One, two, three, or more light emitting units 21 may be formed. The number of tunnel layers 22 is not limited to two and is adjusted in accordance with the number of light emitting units 21.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

What is claimed is:

1. A semiconductor laser device, comprising:
a semiconductor substrate including a substrate main surface and a substrate back surface that face in opposite directions in a first direction, the first direction being orthogonal to the substrate main surface;
a light emitter projecting from the substrate main surface in the first direction and including a contact layer connection surface facing in the first direction and light emitting end surfaces that are two end surfaces in a second direction orthogonal to the first direction;
a contact layer arranged on the contact layer connection surface and including an electrode connection surface facing in the first direction;
an insulation film including two side surface covering portions, two contact layer covering portions, and an opening, the two side surface covering portions covering two side surfaces of the light emitter and two side surfaces of the contact layer in a third direction orthogonal to the first direction and the second direction, the two contact layer covering portions covering two end regions of the electrode connection surface in the third direction, the opening being defined by the two contact layer covering portions and exposing a portion of the electrode connection surface; and
an electrode electrically connected to the electrode connection surface exposed from the opening, wherein
the light emitter is configured to emit laser light from one of the two light emitter end surfaces,
an insulation coverage, which is a ratio of a width of the two contact layer covering portions in the third direction to a width of the electrode connection surface in the third direction, is less than or equal to 10%, and
the contact layer has a thickness that is greater than or equal to 2 μm in the first direction.

2. The semiconductor laser device according to claim 1, wherein the insulation coverage is greater than 0%.

3. The semiconductor laser device according to claim 1, wherein the contact layer has a thickness that is less than or equal to 10 μm in the first direction.

4. The semiconductor laser device according to claim 1, wherein the two contact layer covering portions are equal in width in the third direction.

5. The semiconductor laser device according to claim 1, wherein the light emitter includes at least one light emitting unit including an active layer, and an n-type semiconductor layer and a p-type semiconductor layer sandwiching the active layer in the first direction.

6. The semiconductor laser device according to claim 5, wherein
the at least one light emitting unit includes multiple light emitting units,
the light emitter includes the light emitting units stacked in the first direction,
in each of the light emitting units, the n-type semiconductor layer includes a first n-type clad layer located adjacent to the active layer and a second n-type clad layer located at a side opposite to the active layer with respect to the first n-type clad layer, and
in each of the light emitting units, the p-type semiconductor layer includes a first p-type clad layer located adjacent to the active layer and a second p-type clad layer located at a side opposite to the active layer with respect to the first p-type clad layer.

7. The semiconductor laser device according to claim 5, wherein the light emitting units are stacked with a tunnel layer sandwiched between the light emitting units.

8. The semiconductor laser device according to claim 1, wherein the light emitter has a width in a range of 200 μm to 400 μm in the third direction.

9. The semiconductor laser device according to claim 1, wherein the electrode includes a portion covering the contact layer covering portions.

10. The semiconductor laser device according to claim 1, wherein the contact layer includes a p-type semiconductor material having GaAs.

11. The semiconductor laser device according to claim 1, wherein the semiconductor substrate includes an n-type semiconductor substrate having GaAs.
